(19) United States
(12) Patent Application Publication
(10) Pub. No.: US 2005/0110530 A1
(43) Pub. Date: May 26, 2005

(54) Differential output circuit

(75) Inventors: Masahiro Aoike, Kyoto (JP); Yoshinori Miyada, Kyoto (JP); Takahiro Bokui, Osaka (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 10/988,524

(22) Filed: Nov. 16, 2004

(30) Foreign Application Priority Data
Nov. 21, 2003 (JP) 2003-392214

(51) Int. Cl. H03K 5/22

(52) U.S. Cl. 327/108

(57) ABSTRACT

A differential output circuit which performs data transmission by means of a differential current comprises: a first current source for outputting an electric current to the outside of the circuit; a second current source for introducing an electric current from the outside of the circuit; an output polarity switching circuit for switching the polarity of the differential current generated by the first and second current sources; a voltage source for supplying a predetermined voltage; and a resistor connected between a predetermined node and the voltage source, the predetermined node being interposed between the first and second current sources.

### CROSS-REFERENCE TO RELATED APPLICATION

This application claims priority under 35 U.S.C. §119(a) on Japanese Patent Application No. 2003-392214 filed on Nov. 21, 2003, the entire contents of which are hereby incorporated by reference.

### BACKGROUND OF THE INVENTION

The present invention relates to an interface of a semiconductor device and specifically to a technique of a current-driven interface.

Low Voltage Differential Signaling (hereinafter, referred to as “LVDS”) has been widespread as a current-driven interface. LVDS realizes signal transmission by means of the polarity of the voltage of a small amplitude which occurs at a terminating resistor of a reception side due to a differential current output from a transmission side. LVDS uses a differential signal and is therefore highly immune to common mode noise. However, if a DC offset voltage which is the center of the amplitude of the differential signal is not appropriate to the supply voltage and ground voltage, common mode noise cannot be appropriately canceled. Thus, in LVDS, it is necessary to control the DC offset voltage to be within a predetermined range.

A differential output circuit, which is at the transmission side of LVDS, generally includes a current source which supplies a constant current from a power supply to a terminating resistor of a reception side, a current source which introduces the constant current from the terminating resistor to the ground, and an output polarity switching circuit having a switching element. The differential output circuit performs signal transmission by changing the direction of the differential current using the output polarity switching circuit. The output offset voltage of this differential output circuit is fixed to a voltage such that the current source which supplies the electric current and the current source which introduces the electric current have the same current value. This voltage depends on the characteristics of both of these current sources. The output offset voltage changes according to the variation in the characteristics. Thus, some measure has to be provided for suppressing the characteristic variation of a device during production.

In order to solve this problem, the following measures have been conventionally proposed. Japanese Unexamined Patent Publication No. 2002-84181 discloses providing a constant current circuit section to maintain the output offset voltage at a constant level. U.S. Pat. No. 6,720,805 discloses using a feedback circuit to adjust the bias of a current source in a differential output circuit. U.S. Pat. Nos. 6,380,797 and 6,111,431 disclose using a replica circuit to adjust the bias of a current source in a differential output circuit.

In the case where a feedback circuit is incorporated in a differential output circuit, it is necessary to elaborately design the circuitry such that the control system does not oscillate, and the design complexity increases. Further, providing the constant current circuit section, the feedback circuit, or the replica circuit in the differential output circuit causes not only an increase in circuit scale but also an increase in power consumption.

In the case where the distance of data transmission by LVDS is relatively long, a variation in the output offset voltage is especially large. In such a case, the above-described conventional measures are necessary for adjusting the output offset voltage to be within a level range determined by the standards, although these measures have the disadvantages as described above. However, in the case where the distance of data transmission is relatively short, for example, in the case where LVDS is realized on a single substrate, it is not always necessary to use the constant current circuit section, the feedback circuit, the replica circuit, or the like, for suppressing a variation in the output offset voltage. In this case, the above disadvantages are rather noticeable. Thus, in the case where the distance of data transmission by LVDS is relatively short, it is desirable to control the output offset voltage using a circuit structure having a smallest possible scale.

### SUMMARY OF THE INVENTION

In view of the above, an objective of the present invention is to correct the output offset voltage of a differential output circuit using a small-scale circuit structure which can readily be designed.

A measure taken by the present invention for achieving the above objective is a differential output circuit which performs data transmission by means of a differential current, the differential output circuit comprising: a first current source for outputting an electric current to the outside of the circuit; a second current source for introducing an electric current from the outside of the circuit; an output polarity switching circuit for switching the polarity of the differential current generated by the first and second current sources; a voltage source for supplying a predetermined voltage; and a resistor connected between a predetermined node and the voltage source, the predetermined node being interposed between the first and second current sources.

With the above structure, an error current generated between the first current source and the second current source is absorbed by a voltage source through a resistor connected to the voltage source. As a result, the variation of the output offset voltage is suppressed. That is, the output offset voltage is corrected.

Preferably, any one of the first and second current sources has a current value larger than that of the other current source, and the other current source is connected to the voltage source.

More preferably, the first current source has a current value larger than that of the second current source, and the voltage source is a ground node.

More preferably, the second current source has a current value larger than that of the first current source, and the voltage source is a power supply node.

In the above differential output circuit, each of the first and second current sources is preferably a variable current source.

Specifically, the predetermined node is a connection point between any one of the first and second current sources and the output polarity switching circuit.

Specifically, the predetermined node is an output terminal of the differential current.

As described above, according to the present invention, a differential output circuit capable of correcting the output offset voltage is realized by a circuit having a relatively small scale and a simple structure. Thus, for example, in the case where the differential output circuit of the present invention is used in an interface component between LSI devices, the area occupation ratio of an interface circuit decreases, and the cost of the LSI devices decreases.

### BRIEF DESCRIPTION OF THE DRAWINGS

FIG. 1 shows a structure of a differential output circuit according to embodiment 1 of the present invention.

FIG. 2 shows a structure of a differential output circuit according to embodiment 2 of the present invention.

FIG. 3 shows a variation of the differential output circuit of FIG. 2.

FIG. 4 shows a structure of a differential output circuit according to embodiment 3 of the present invention.

FIG. 5 shows a structure of a differential output circuit according to embodiment 4 of the present invention.

FIG. 6 shows a variation of the differential output circuit of FIG. 5.

FIG. 7 shows a structure of a differential output circuit according to embodiment 5 of the present invention.

FIG. 8 shows a variation of the differential output circuit of FIG. 7.

### BEST MODE FOR CARRYING OUT THE INVENTION

Hereinafter, the best modes for carrying out the present invention will be described with reference to the drawings.

### Embodiment 1

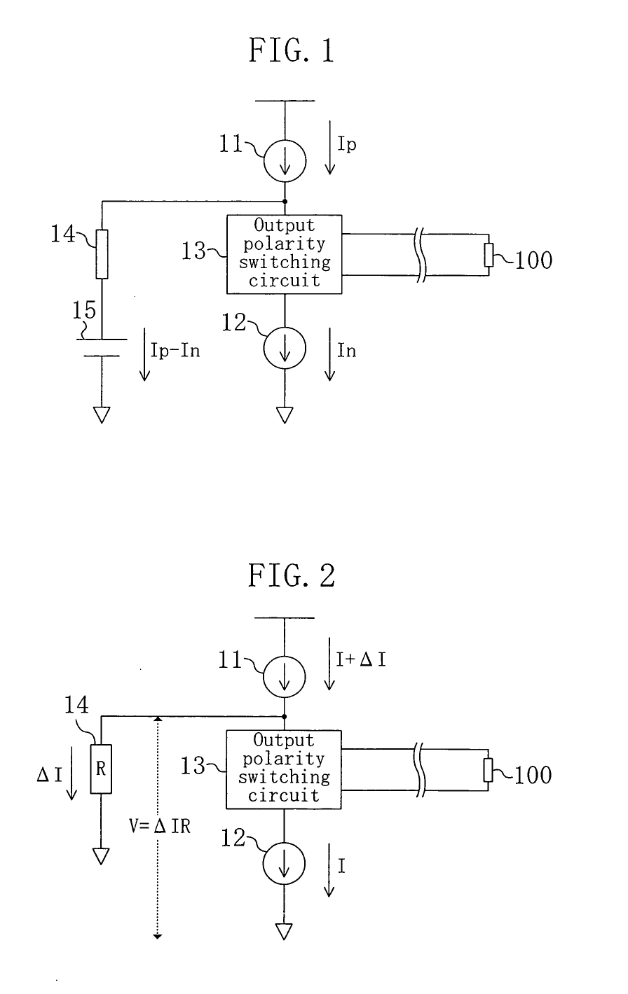

FIG. 1 shows a structure of a differential output circuit according to embodiment 1 of the present invention. The differential output circuit of embodiment 1 includes a current source 11 for supplying a constant current from a power supply to a terminating resistor 100 of a reception circuit (not shown), a current source 12 for introducing a constant current from the terminating resistor 100 to the ground, an output polarity switching circuit 13 interposed between the current source 11 and the current source 12, a resistor 14, and a voltage source 15. An end of the resistor 14 is connected to a connection point between the current source 11 and the output polarity switching circuit 13. The other end of the resistor 14 is connected to the voltage source 15. The voltage source 15 supplies a predetermined voltage, for example, about a half of supply voltage VDD.

In the differential output circuit of embodiment 1, a differential current is generated by the current sources 11 and 12. The output polarity switching circuit 13 switches the polarity of the differential current according to supplied transmission data (not shown). With this structure, the direction of an electric current flowing through the terminating resistor 100 is switched. The reception circuit obtains reception data based on the polarity of a voltage generated at the terminating resistor 100.

Current value Ip of the current source 11 is ideally equal to current value In of the current source 12, but in actuality, there is a small error (Ip−In) between these values due to production variations, or the like. As previously described, this error constitutes the reason of the variation in the output offset voltage of the differential output circuit. In the differential output circuit of embodiment 1, when current value Ip is larger than current value In, an error current having current value Ip−In flows into the voltage source 15. When current value Ip is smaller than current value In, an error current having current value In−Ip flows from the voltage source 15. That is, the error current is absorbed by the voltage source 15 through the resistor 14, whereby a variation in the output offset voltage is suppressed.

The resistor 14 may be connected to the connection point between the current source 12 and the output polarity switching circuit 13 instead of the connection point between the current source 11 and the output polarity switching circuit 13.

### Embodiment 2

FIG. 2 shows a structure of a differential output circuit according to embodiment 2 of the present invention. The differential output circuit of embodiment 2 includes a current source 11 for supplying a constant current from a power supply to a terminating resistor 100 of a reception circuit (not shown), a current source 12 for introducing a constant current from the terminating resistor 100 to the ground, an output polarity switching circuit 13 interposed between the current source 11 and the current source 12, and a resistor 14. The current value of the current source 11 is set to be larger than current value I of the current source 12 by ΔI. For example, the current source 11 may be formed by a current source having the same current value as that of the current source 12 and a current source having current value ΔI which are connected in parallel. An end of the resistor 14 is connected to a connection point between the current source 11 and the output polarity switching circuit 13. The other end of the resistor 14 is connected to a ground node that is a voltage source to which the current source 12 is connected.

In the differential output circuit of embodiment 2, a differential current generated between the current sources 11 and 12 (current value ΔI) flows into the ground node through the resistor 14. In this case, a potential difference, represented by ΔIR, occurs between the ends of the resistor 14. Thus, the voltage at the connection point between the current source 11 and the output polarity switching circuit 13 to which the resistor 14 is connected is higher than the ground potential by ΔIR. That is, the output offset voltage is maintained to be constant with respect to the ground potential.

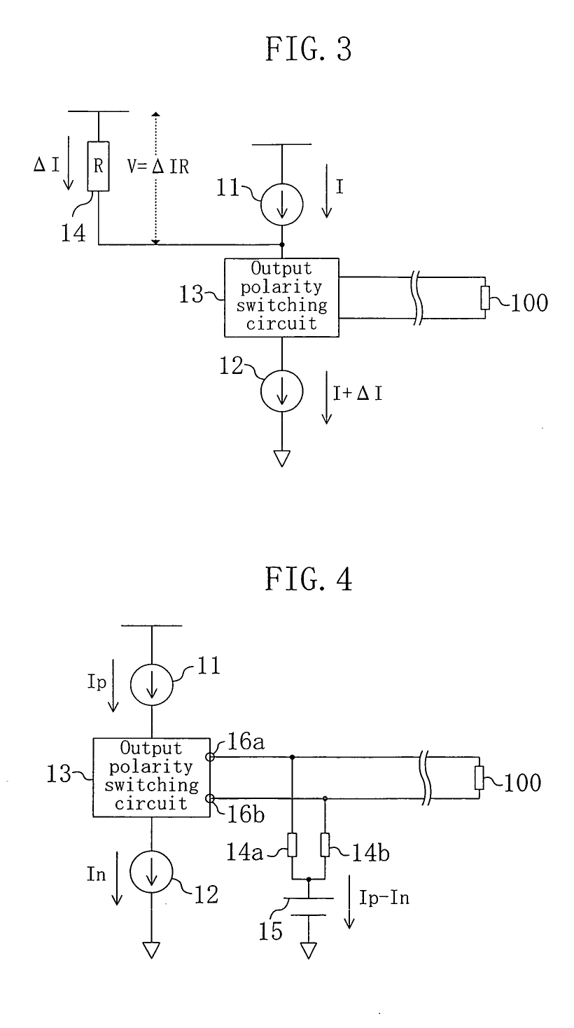

Alternatively, as shown in FIG. 3, instead of the ground node, the resistor 14 may be connected to a power supply node that is the voltage source to which the current source 11 is connected. In this case, the current value of the current source 12 is set to be larger than current value I of the current source 11 by ΔI. In the differential output circuit of FIG. 3, a differential current generated between the current sources 11 and 12 (current value ΔI) flows from the power supply node through the resistor 14. In this case, a potential difference, represented by ΔIR, occurs between the ends of the resistor 14. Thus, the voltage at the connection point between the current source 11 and the output polarity switching circuit 13 to which the resistor 14 is connected is lower than the supply potential by ΔIR. That is, the output offset voltage is maintained to be constant with respect to the supply potential.

In the differential output circuits of FIGS. 2 and 3, the resistor 14 may be connected to the connection point between the current source 12 and the output polarity switching circuit 13 instead of the connection point between the current source 11 and the output polarity switching circuit 13.

### Embodiment 3

FIG. 4 shows a structure of a differential output circuit according to embodiment 3 of the present invention. The differential output circuit of embodiment 3 includes a current source 11 for supplying a constant current from a power supply to a terminating resistor 100 of a reception circuit (not shown), a current source 12 for introducing a constant current from the terminating resistor 100 to the ground, an output polarity switching circuit 13 interposed between the current source 11 and the current source 12, resistors 14a and 14b, and a voltage source 15. An end of the resistor 14a is connected to an output terminal 16a of a differential current. The other end of the resistor 14a is connected to the voltage source 15. An end of the resistor 14b is connected to an output terminal 16b of the differential current. The other end of the resistor 14b is connected to the voltage source 15. The voltage source 15 supplies a predetermined voltage, for example, about a half of supply voltage VDD.

In the differential output circuit of embodiment 3, when current value Ip is larger than current value In, an error current having current value Ip−In flows into the voltage source 15. When current value Ip is smaller than current value In, an error current having current value In−Ip flows from the voltage source 15. Thus, the error current generated between the current sources 11 and 12 is absorbed by the voltage source 15 through the resistors 14a and 14b, whereby a variation in the output offset voltage is suppressed.

### Embodiment 4

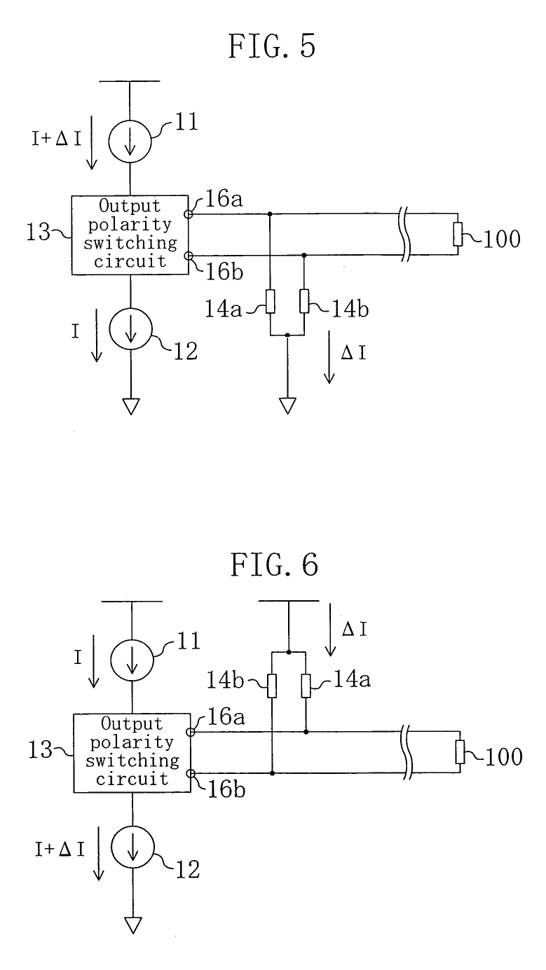

FIG. 5 shows a structure of a differential output circuit according to embodiment 4 of the present invention. The differential output circuit of embodiment 4 includes a current source 11 for supplying a constant current from a power supply to a terminating resistor 100 of a reception circuit (not shown), a current source 12 for introducing a constant current from the terminating resistor 100 to the ground, an output polarity switching circuit 13 interposed between the current sources 11 and 12, and resistors 14a and 14b. The current value of the current source 11 is set to be larger than current value I of the current source 12 by ΔI. For example, the current source 11 may be formed by a current source having the same current value as that of the current source 12 and a current source having current value ΔI which are connected in parallel. An end of the resistor 14a is connected to an output terminal 16a of a differential current. The other end of the resistor 14a is connected to a ground node that is a voltage source to which the current source 12 is connected. An end of the resistor 14b is connected to an output terminal 16b of the differential current. The other end of the resistor 14b is connected to the ground node that is the voltage source to which the current source 12 is connected.

In the differential output circuit of embodiment 4, a differential current generated between the current sources 11 and 12 (current value ΔI) flows into the ground node through the resistors 14a and 14b. As a result, a predetermined voltage which is determined by the magnitude of the differential current between the current source 11 and the current source 12 occurs at the resistors 14a and 14b, and the output offset voltage is maintained to be constant with respect to the ground potential.

Alternatively, as shown in FIG. 6, instead of the ground node, the resistors 14a and 14b may be connected to a power supply node that is the voltage source to which the current source 11 is connected. In this case, the current value of the current source 12 is set to be larger than current value I of the current source 11 by ΔI. In the differential output circuit of FIG. 6, a differential current generated between the current source 11 and the current source 12 (current value ΔI) flows from the power supply node through the resistors 14a and 14b. As a result, a predetermined voltage which is determined by the magnitude of the differential current between the current source 11 and the current source 12 occurs at the resistors 14a and 14b, and the output offset voltage is maintained to be constant with respect to the power supply potential.

### Embodiment 5

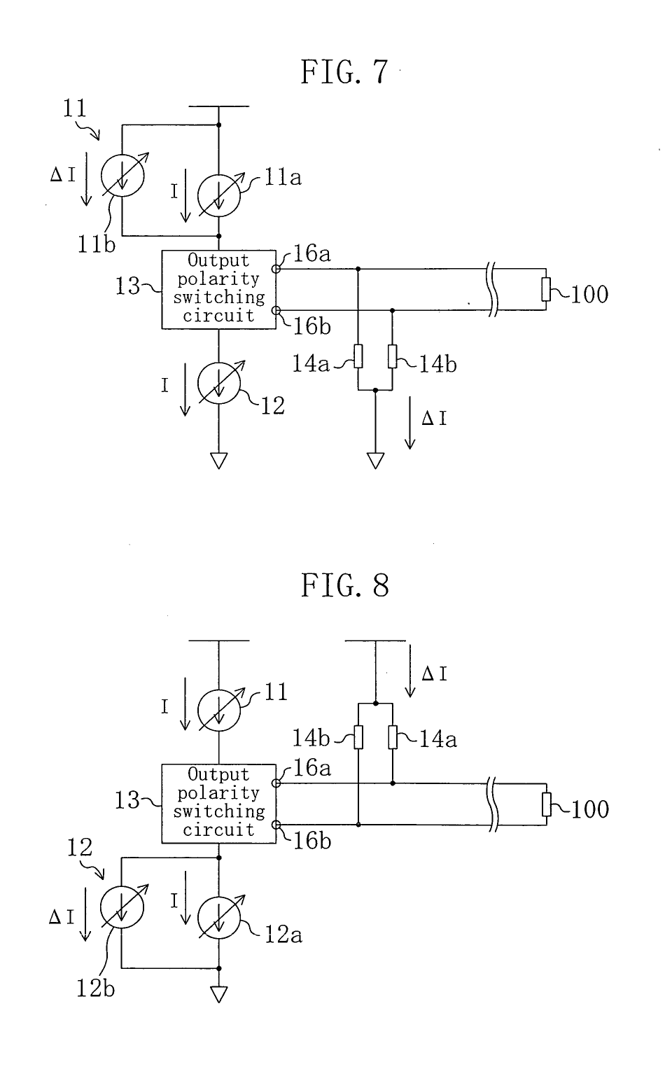

FIG. 7 shows a structure of a differential output circuit according to embodiment 5 of the present invention. The differential output circuit of embodiment 5 includes a current source 11 for supplying a constant current from a power supply to a terminating resistor 100 of a reception circuit (not shown), a current source 12 for introducing a constant current from the terminating resistor 100 to the ground, an output polarity switching circuit 13 interposed between the current sources 11 and 12, and resistors 14a and 14b. The current source 11 is formed by current sources 11a and 11b which are connected in parallel. The current value of the current source 11a is I, which is equal to the current value of the current source 12. The current value of the current source 11b is ΔI. It should be noted that each of the current sources 11a, 11b and 12 is a variable current source in which the current value can be changed. An end of the resistor 14a is connected to an output terminal 16a of a differential current. The other end of the resistor 14a is connected to a ground node that is a voltage source to which the current source 12 is connected. An end of the resistor 14b is connected to an output terminal 16b of the differential current. The other end of the resistor 14b is connected to the ground node that is the voltage source to which the current source 12 is connected.

In the differential output circuit of embodiment 5, an electric current having current value ΔI, which is supplied by the current source 11b, flows into the ground node through the resistors 14a and 14b. As a result, a predetermined voltage which is determined by current value ΔI occurs at the resistors 14a and 14b. Thus, the output offset voltage is maintained to be constant with respect to the ground potential. The output offset voltage can be adjusted by adjusting the current value of the current source 11b. Further, the amplitude which occurs at the terminating resistor 100 can be adjusted by adjusting the current values of the current sources 11a and 12.

As described above, according to embodiment 5, the reception signal level and the output offset voltage at the reception circuit side are adjustable.

Alternatively, as shown in FIG. 8, instead of the ground node, the resistors 14a and 14b may be connected to a power supply node that is the voltage source to which the current source 11 is connected. In this case, a current source 12a having current value I, which is equal to that of the current source 11, and a current source 12b having current value ΔI are connected in parallel to form the current source 12. In the differential output circuit of FIG. 8, the electric current of current value ΔI, which is introduced by the current source 12b, flows from the power supply node through the resistors 14a and 14b. As a result, a predetermined voltage which is determined by current value ΔI occurs at the resistors 14a and 14b. That is, the output offset voltage is maintained to be constant with respect to the power supply potential. The output offset voltage can be adjusted by adjusting the current value of the current source 12b. Further, the amplitude which occurs at the terminating resistor 100 can be adjusted by adjusting the current values of the current sources 11 and 12a.

As described above, in a differential output circuit of the present invention, correction of the output offset voltage is possible with a circuit which has a relatively small scale and a simple structure. Thus, such a differential output circuit is useful as an interface component in a communication system between LSI devices.

1. A differential output circuit which performs data transmission by means of a differential current, comprising:
a first current source for outputting an electric current to the outside of the circuit;
a second current source for introducing an electric current from the outside of the circuit;
an output polarity switching circuit for switching the polarity of the differential current generated by the first and second current sources;
a voltage source for supplying a predetermined voltage; and
a resistor connected between a predetermined node and the voltage source, the predetermined node being interposed between the first and second current sources.

2. The differential output circuit of claim 1, wherein:
any one of the first and second current sources has a current value larger than that of the other current source; and
the other current source is connected to the voltage source.

3. The differential output circuit of claim 2, wherein:
the first current source has a current value larger than that of the second current source; and
the voltage source is a ground node.

4. The differential output circuit of claim 2, wherein:
the second current source has a current value larger than that of the first current source; and
the voltage source is a power supply node.

5. The differential output circuit of claim 1, wherein each of the first and second current sources is a variable current source.

6. The differential output circuit of claim 1, wherein the predetermined node is a connection point between any one of the first and second current sources and the output polarity switching circuit.

7. The differential output circuit of claim 1, wherein the predetermined node is an output terminal of the differential current.
